(19) United States
(12) Patent Application Publication
(10) Pub. No.: US 2026/0164771 A1
(43) Pub. Date: Jun. 11, 2026

(54) SEMICONDUCTOR DISLOCATION-BASED PHYSICALLY UNCLONABLE FUNCTION AND METHOD

(71) Applicant: GlobalFoundries U.S. Inc., Malta, NY (US)

(72) Inventors: Ivan Krasimirov Kanev, Sofia (BG); Nayden Petkov Nedev, Sofia (BG)

(21) Appl. No.: 18/973,899

(22) Filed: Dec. 9, 2024

(51) Int. Cl. H10D 84/83; H10D 62/10

(52) U.S. Cl. CPC H10D 84/83; H10D 62/124

(57) ABSTRACT

A cell structure for a physically unclonable function (PUF) includes a field effect transistor (FET) with an active semiconductor region having opposing sides. One side is linear and the other is stepped or curved so the active semiconductor region has a first portion with a first width and a second portion with a greater second width. The FET also includes a gate with first and second gate fingers electrically connected and traversing the first and second portions, respectively. Optionally, the cell structure includes semiconductor fill material region(s) adjacent to at least one end and/or at least one side. Optionally, the cell structure includes a pair of mirror-image FETs. Various dimensions within the cell structure are predetermined to achieve an approximately random likelihood that the off-state drain current (Idoff) will be at any particular Idoff level within a relatively large range of possible Idoff levels, due to random occurrence of dislocation(s).

### BACKGROUND

The present disclosure relates to physically unclonable functions (PUFs) and, more particularly, to embodiments of a cell structure for a PUF, a PUF, and associated methods.

With the ever-increasing use of Internet of Things (IoT) objects, wireless communications and data are becoming increasingly vulnerable to a wide range of security threats. To protect against such security threats, various circuits, which are referred to as Physically Unclonable Functions (PUFs), have been developed for cryptography (e.g., encryption and decryption), advanced authentication, etc. Generally, a PUF is an on-chip random number generator configured to consistently generate and output a particular valid response (e.g., a particular random bitstring) whenever a valid challenge is received. Unfortunately, with currently available PUFs, a truly random bitstring may not be possible, area consumption may be relatively large, and/or the circuit itself may be relatively complex.

### SUMMARY

Disclosed herein are embodiments of a cell structure for a physically unclonable function (PUF) (also referred to herein as a PUF cell). The PUF cell can include at least one field effect transistor (FET). The FET can include an active semiconductor region. The active semiconductor region can include a first portion and a second portion. The first portion can have a first width. The second portion can be continuous with the first portion and can have a second width that is greater than the first width. The FET can also include a gate. The gate can include a first gate section, which traverses the first portion, and a second gate section, which is electrically connected to the first gate section and which traverses the second portion.

Also disclosed herein are embodiments of a PUF structure (also referred to herein simply as a PUF).

In some embodiments, a PUF can include a device (also referred to herein as a device under test (DUT)). The DUT can include multiple cell structures (i.e., multiple PUF cells). Each PUF cell can include at least one FET. The FET can include an active semiconductor region with a first end and a second end opposite the first end. The active semiconductor region can include a first portion at the first end and a second portion, which is continuous with the first portion and which extends to the second end. The first portion can have a first width and the second portion can be continuous with the first portion and can have a second width that is greater than the first width. The FET can also include a gate. The gate can include a first gate section, which traverses the first portion and a second gate section, which is electrically connected to the first gate section and which traverses the second portion. Within the FET, the active semiconductor region can include a source region in the first portion adjacent to the first end, a drain region in the second portion adjacent to the second end, and a shared source/drain region between the first gate section and the second gate section. The PUF can also include a set of pads for the DUT. The pads in the set can include at least: a first pad connected to gates of field effect transistors of the PUF cells therein; a second pad connected to source regions of the field effect transistor of the PUF cells therein; and a third pad connected to drain regions of the field effect transistors of the PUF cells therein.

In other embodiments, a PUF can include multiple devices (i.e., multiple DUTs). Each DUT can include multiple cell structures (i.e., multiple PUF cells). Each PUF cell can include at least one FET. The FET can include an active semiconductor region with a first end and a second end opposite the first end. The active semiconductor region can include a first portion at the first end and a second portion, which is continuous with the first portion and which extends to the second end. The first portion can have a first width and the second portion can be continuous with the first portion and can have a second width that is greater than the first width. The FET can also include a gate. The gate can include a first gate section, which traverses the first portion and a second gate section, which is electrically connected to the first gate section and which traverses the second portion. Within the FET, the active semiconductor region can include a source region in the first portion adjacent to the first end, a drain region in the second portion adjacent to the second end, and a shared source/drain region between the first gate section and the second gate section. The PUF can also include multiple sets of pads for the DUTs, respectively. The pads in each set for each DUT can include at least: a first pad connected to gates of field effect transistors of the PUF cells of the DUT; a second pad connected to source regions of the field effect transistor of the PUF cells of the DUT; and a third pad connected to drain regions of the field effect transistors of the PUF cells of the DUT.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is drawing illustrating an example layout for disclosed PUF cell embodiments;

FIG. 2 is a schematic diagram illustrating disclosed PUF embodiments;

FIG. 3 is a schematic diagram illustrating other disclosed PUF embodiments;

FIGS. 4A and 4B are drawings further illustrating the example layout of FIG. 1 with dislocations in the active semiconductor region of one or more FETs of the PUF cell;

FIG. 5 is a flow diagram illustrating a calibration process that may be performed during design of the PUF cell of FIG. 1;

FIG. 6 is a drawing further illustrating the example layout of FIG. 1 annotated to show at least some dimensions that are modifiable during the calibration process of FIG. 5; and

FIG. 7 is a graph illustrating example off-state drain leakage currents (Idoffs) plotted for different PUF cell designs during the calibration process of FIG. 5.

### DETAILED DESCRIPTION

As mentioned above, with the ever-increasing use of Internet of Things (IoT) objects, wireless communications and data are becoming increasingly vulnerable to a wide range of security threats. To protect against such security threats, various circuits known as Physically Unclonable Functions (PUFs) have been developed for cryptography (e.g., encryption and decryption), advanced authentication, etc. Generally, a PUF is an on-chip random number generator configured to consistently generate and output a particular valid response (e.g., a particular random bitstring) whenever a valid challenge is received. Unfortunately, with currently available PUFs, a truly random bitstring may not be possible, area consumption may be relatively large, and/or the circuit itself may be relatively complex.

In view of the foregoing, disclosed herein are embodiments of a cell structure for a Physically Unclonable Function (PUF). The cell structure (also referred to herein as the PUF cell) can include at least one field effect transistor (FET) with a uniquely designed active semiconductor region. Specifically, the active semiconductor region can have opposing ends and opposing sides extending between the opposing ends. One side can be essentially linear and the other can be stepped (or alternatively, curved) such that the active semiconductor region has portions with progressively increasing widths between the ends. For example, the active semiconductor region can include a first portion with a first width and a second portion with a second width that is greater than the first width. The FET can further include a gate with electrically connected gate fingers traversing the active semiconductor region (e.g., a first gate finger traversing the first portion and a second gate finger electrically connected to the first gate finger and traversing the second portion). Optionally, the PUF cell can include semiconductor fill material region(s) adjacent to at least one end and/or at least one of side of the active semiconductor region. Optionally, the PUF cell can include a pair of mirror-image FETs (optionally with corresponding adjacent semiconductor fill material region(s)) and these FETs can have a shared gate (i.e., the gate fingers can extend laterally across the active semiconductor regions of both FETs).

In any case, each FET within the PUF cell can exhibit a corresponding off-state drain current (Idoff), which falls within a wide range of possible Idoff levels due to the presence or absence of one or more dislocations in the active semiconductor region. For example, a large number of dislocations in the active semiconductor region can result in a significant increase in the corresponding Idoff and vice versa. Embodiments of the disclosed PUF cell use such dislocations to achieve random performance variations. Specifically, during PUF cell design a calibration process can be performed. The calibration process can include selecting certain dimensions associated with the active semiconductor region to adjust inherent stress on the active semiconductor region and thereby increase the likelihood, to some degree, that one or more dislocations will be present within the active semiconductor region following manufacturing. The goal of the calibration process is to generate a final PUF cell design, which ensures that the Idoff of any FET within a PUF cell manufactured according to the final PUF design will fall within a relatively large range of possible Idoffs and further will be approximately equally as likely to be above or below some mid-level within that range (due to the probability of the occurrence of dislocations therein).

Also disclosed herein are embodiments of a PUF, which includes one or more devices (also referred to herein as devices under test (DUTs)). Each DUT can include a corresponding array of PUF cells, as described above. Thus, dislocations will be randomly distributed and the actual Idoff values of the FETs therein will vary essentially randomly. Consequently, the Idoffs exhibited by all FETs within a DUT can be concurrently read out and summed and the resulting total Idoff of the DUT can be used to generate a digital output (Dout) (e.g., bitstring through the use of an analog-to-digital converter (ADC) of a sense circuit). The total Idoff of a DUT configured in this manner can be repeatedly and consistently generated and, thus, so can Dout. Optionally, multiple DUTs can be incorporated into a PUF to, for example, achieve a stronger PUF (i.e., a PUF with a larger number of challenge-response pairs). Also disclosed herein are embodiments of associated design, manufacture, and operation methods. Optionally, such methods can include monitoring the PUF for early detection of degradation, as discussed in greater detail below.

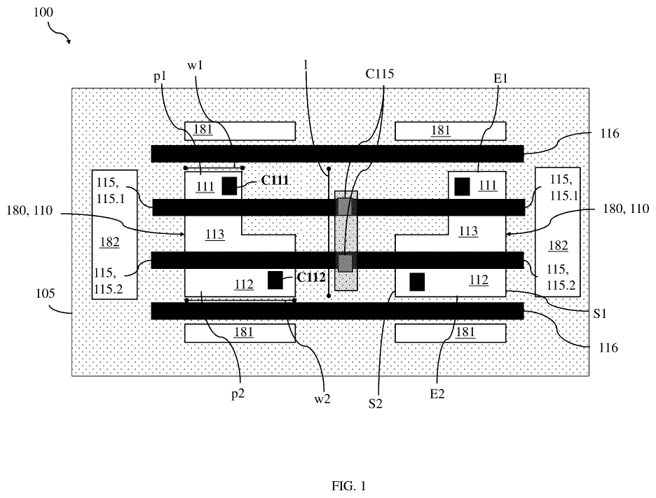

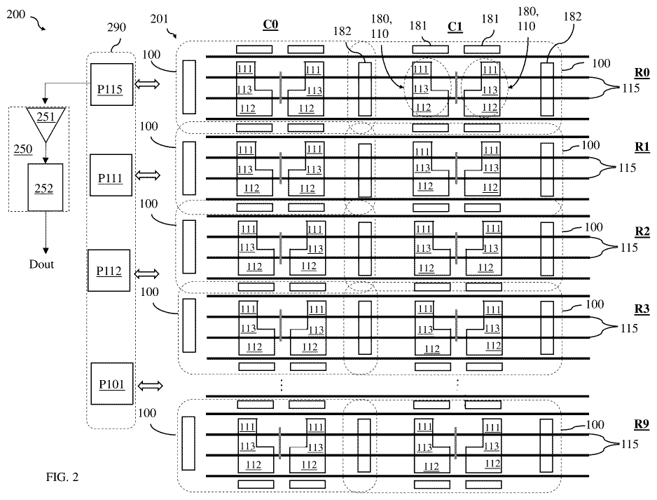

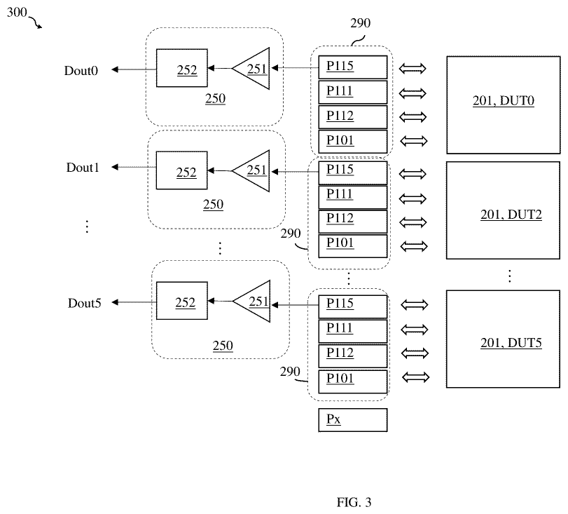

FIG. 1 is illustrates a design layout for disclosed embodiments of a cell structure for a Physically Unclonable Function (PUF). This cell structure is also referred to herein as a PUF cell 100. FIG. 2 is a schematic diagram illustrating disclosed embodiments of a PUF 200 including a device (also referred to herein as a device under test (DUT) 201), which incorporates multiple PUF cells 100, as described in greater detail below and illustrated in FIG. 1. FIG. 3 is a schematic diagram illustrating additional disclosed embodiments of a PUF 300 including multiple DUTs 201, as described in greater detail below and illustrated in FIG. 2. It should be noted that each of the structure disclosed herein (i.e., PUF cell 100, as illustrated in FIG. 1, PUF 200 with a DUT 201 including multiple PUF cells 100, as illustrated in FIG. 2, and PUF 300 with multiple DUTs 201, as illustrated in FIG. 3) are semiconductor structures.

Each semiconductor structure can include a monocrystalline semiconductor layer with a first surface (e.g., a bottom surface) and a second surface (e.g., a top surface) opposite the first surface. In some embodiments, the monocrystalline semiconductor layer could be a bulk semiconductor substrate (e.g., a bulk silicon (Si) substrate or a bulk substrate of any other suitable semiconductor material, such as germanium (Ge), silicon germanium (SiGe), etc.). Alternatively, the monocrystalline semiconductor layer could be the semiconductor layer (e.g., a Si layer, a Ge layer, a SiGe layer, or a layer any other suitable semiconductor material) of a semiconductor-on-insulator structure (e.g., a silicon-on-insulator (SOI) structure, a germanium-on-insulator structure, a silicon germanium-on-insulator structure, etc.) such that the first surface is above and immediately adjacent to an insulator layer (not shown) and the insulator layer is on a substrate (e.g., a semiconductor substrate, such as a silicon substrate, or some other suitable type of substrate). Alternatively, the monocrystalline semiconductor layer could be in a bulk region or a semiconductor-on-insulator region (e.g., an SOI region, etc.) of a hybrid substrate. Those skilled in the art will recognize that hybrid substrates are typically employed at an advanced technology node, such as a fully-depleted or partially-depleted SOI technology node, and include bulk regions and semiconductor-on-insulator regions.

Referring to FIG. 1, PUF cell 100 can include a planar field effect transistor (FET) 110. Optionally, PUF cell 100 can include a pair of planar FETs 110, as illustrated (i.e., a FET and an additional FET). These FETs 110 can be, for example, symmetrically oriented (i.e., mirror-image FETs).

In any case, each FET 110 can include an active semiconductor region 180 within the semiconductor layer. The active semiconductor region 180 can be uniquely designed. Specifically, the active semiconductor region 180 can have opposing ends (i.e., a first end (E1) and a second end (E2) opposite E1) and opposing sides (i.e., a first side (S1) and a second side (S2) opposite S1), which extend laterally between the opposing ends. E1 and E2 can be essentially linear and parallel to each other. S1 can also be essentially linear, whereas S2 can be stepped (as illustrated) or curved (not shown) such that active semiconductor region 180 has portions with progressively increasing widths between E1 and E2. For example, active semiconductor region 180 can include a first portion (p1) with a first width (w1) and a second portion (p2) with a second width (w2) that is greater than w1. Active semiconductor region 180 can be laterally surrounded by an isolation region 105. Isolation region 105 can, for example, be a shallow trench isolation (STI) region. Such an STI region can include a trench, which is formed (e.g., lithographically patterned and etched) so as to extend into the semiconductor layer from the top surface downward and so as to define the outer boundaries of the shape of active semiconductor region 180. Thus, as illustrated, the trench of the STI region can be formed so as to define an essentially L-shaped active semiconductor region. The STI region can further include one or more layers of isolation material (e.g., silicon dioxide (SiO2), silicon oxynitride (SiON), or some other suitable isolation material) that fills the trench. In embodiments where PUF cell 100 includes a pair of FETs 110, the active semiconductor regions 180 of the two FETs 110 can be essentially identical in size and shape, symmetrically oriented (i.e., mirror-image FETs), and physically separated by isolation region 105. In some embodiments, as illustrated, S2 of each active semiconductor region 180 could be adjacent to the center of PUF cell 100 and S1 of each active semiconductor region 180 could be adjacent the outer edges of PUF cell 100. In other embodiments, not shown, S1 of each active semiconductor region 180 could be adjacent the center of PUF cell 100 and S2 of each active semiconductor region 180 could be adjacent the outer edges of PUF cell 100.

Optionally, PUF cell 100 can include one or more semiconductor fill material regions 181-182 adjacent to at least one end (E1 and/or E2) and/or at least one side (S1 and/or S2) of each active semiconductor region 180. Each semiconductor fill material region can, like active semiconductor region 180, be a portion of the semiconductor layer having boundaries defined by isolation region 105 (i.e., isolation region 105 can laterally surround each semiconductor fill material region) such that they are physically separated from the adjacent active semiconductor region by isolation material. The semiconductor fill material region(s) can, for example, be essentially rectangular in shape.

In some embodiments, discrete first semiconductor fill material regions 181 can be parallel to E1 and E2 of each active semiconductor region 180, and a second semiconductor fill material region 182 can be adjacent to one side of the active semiconductor region 180 (e.g., S1) at an outer edge of PUF cell 100. In some embodiments, first semiconductor fill material regions 181 at opposite ends can have equal widths. For example, the first semiconductor fill material regions 181 can have a width that is essentially equal to the second width (w2) of the second portion (p2) of the active semiconductor region 180, as illustrated. Alternatively, the first semiconductor fill material regions 181 could have different widths from each other and/or different widths relative to the first width (w1) of the first portion (p1) and/or the second width (w2) of the second portion (p2) of the active semiconductor region 180. In some embodiments, the length of second semiconductor fill material region 182 can be the same as the length (l) of the active semiconductor region 180. Alternatively, the length of second semiconductor fill material region 182 could be different from (e.g., longer, or shorter than) the length (l) of the active semiconductor region 180. In any case, in embodiments where PUF cell 100 includes a pair of FETs 110, the semiconductor fill material region(s) 181-182 adjacent to the corresponding active semiconductor regions 180 of the two FETs 110 can be essentially identical in size and shape and symmetrically oriented.

Each FET 110 can further include a gate 115. Gate 115 can include a gate stack including a gate dielectric layer (including one or more layers of gate dielectric material) and a gate conductor layer (including one or more layers of gate conductor material) on the gate dielectric layer. Such a gate 115 could be a gate first polysilicon gate, a gate first high-K metal gate, a replacement metal gate, etc. Various different gate configurations for FETs are well known in the art. Thus, the details thereof have been omitted from this specification to allow the reader to focus on the salient aspects of the disclosed embodiments. In any case, gate 115 can be a multi-finger gate structure. For example, gate 115 can include: a first gate section 115.1 (also referred to herein as a first gate finger), which traverses p1 (i.e., the narrow portion with width w1); and a second gate section 115.2 (also referred to herein as a second gate finger), which traverses p2 (i.e., the wider portion with width w2). First gate section 115.1 can define a first channel region within p1 and second gate section 115.2 can define a second channel region within p2. Additionally, first and second gate sections 115.1 and 115.2 can be electrically connected. For example, as illustrated, a pair of gate contacts landing on first gate section 115.1 and second gate section 115.2 could be electrically connected by a back end of the line (BEOL) metal wire. Alternatively, some other technique could be employed to electrically connect the two gate sections 115.1-115.2. For example, during gate formation, a gate extension could be formed (e.g., lithographically patterned and etched) so that it is perpendicular to and extends laterally across isolation region 105 between the two gate sections 115.1-115.2. In embodiments where PUF cell 100 includes a pair of FETs 110, gate 115 can be shared between the FETs 110. That is, first gate section 115.1 and second gate section 115.2 can traverse p1 and p2 of the active semiconductor regions 180 of both FETs 110.

Optionally, PUF cell 100 can include non-functional gate structures 116 (also referred to herein as dummy gate structures or dummy gates). Such dummy gates 116 can be formed (e.g., lithographically patterned and etched) during gate 115 formation so as to have the same gate stack materials as gate 115. However, dummy gates 116 can be located on isolation region 105 parallel to ends E1 and E2 of the active semiconductor region(s) 180 (e.g., between active semiconductor region(s) 180 and adjacent semiconductor fill material regions 181).

Each FET 110 can further include, within active semiconductor region 180, a source region 111 p1 adjacent to E1, a drain region 112 in p2 adjacent to E2, and a shared source/drain region 113 between first gate section 115.1 and second gate section 115.2. As illustrated, a portion of shared source/drain region 113 is in p1 adjacent to first gate section 115.1 and, thus, has first width w1. Another portion of shared source/drain region 113 is in p2 adjacent to second gate section 115.2 and, thus, has second width w2. In some embodiments, FET(s) 110 of PUF cell 100 can be N-type field effect transistors (NFETs). Those skilled in the art will recognize that in an NFET, regions 111-113 can be doped so as to have N-type conductivity at a relatively high conductivity level (e.g., so as to be N+ regions) and channel regions therebetween can be either undoped or doped so as to have P-type conductivity at a relatively low conductivity level (e.g., so as to be intrinsic regions or P− regions). In other embodiments, FET(s) 110 of PUF cell 100 could be P-type field effect transistors (PFETs). Those skilled in the art will recognize that in a PFET, regions 111-113 can be doped so as to have P-type conductivity at a relatively high conductivity level (e.g., so as to be P+ regions) and channel regions therebetween can be either undoped or doped so as to have N-type conductivity at a relatively low conductivity level (e.g., so as to be intrinsic regions or N− regions).

It should be understood that PUF cell 100 can further include gate sidewall spacers (not shown), which are positioned laterally adjacent to the opposing sidewalls of first and second gate sections 115.1-115.2 of gate 115. Gate sidewall spacers can be made of one or more layers of dielectric spacer material, such as SiO2 and/or any other suitable dielectric spacer material, so as to electrically isolate gate 115 from regions 111-113. Various different gate sidewall spacer configurations are known in the art. Thus, the details thereof have been omitted from this specification to allow the reader to focus on the salient aspects of the disclosed embodiments.

Additionally, it should be understood that PUF cell 100 can be covered with one or more layers of interlayer dielectric (ILD) material (not shown). ILD material can include, for example, a conformal etch stop layer (e.g., a silicon nitride (SiN) layer) and, on the etch stop layer, a blanket layer of SiO₂ doped silicon glass, such as phosphosilicate glass (PSG) or borophosphosilicate glass (BPSG), or any other suitable ILD material. PUF cell 100 can further include middle of the line (MOL) contacts extending through the ILD material at least to source region 111 (see contact C111), drain region 112 (see contact C112), and gate 115 (see contact C115) of each FET 110. Optionally, a MOL contact can also extend through ILD material and isolation region 105 to device body region (not shown).

In any case, a FET 110 in PUF cell 100 can exhibit a corresponding off-state drain current (Idoff), which falls within a wide range of possible Idoff levels due to the presence or absence of one or more dislocations in active semiconductor region 180. Specifically, those skilled in the art will recognize that Idoff refers to the leakage current the passes through a FET, when the FET should be in an off-state given the bias conditions thereof. Additionally, a dislocation in a monocrystalline semiconductor material, such as silicon, refers to a linear defect (e.g., a localized misalignment). Such dislocations can create irregularities in the lattice structure of the active semiconductor region 180 and these irregularities can, in turn, cause variations in the electrical characteristics of the FET 110 (e.g., a change in charge carrier mobility as compared to other FETs manufactured according to the same PUF cell design, a change in carrier concentration as compared to other FETs manufactured according to the same PUF cell design, etc.). Changes in such electrical characteristics can cause a change in threshold voltage (Vt). Increasing the number of dislocations within active semiconductor region 180 can cause a significant increase in Idoff, whereas reducing or preventing dislocations can cause little to no increase in Idoff.

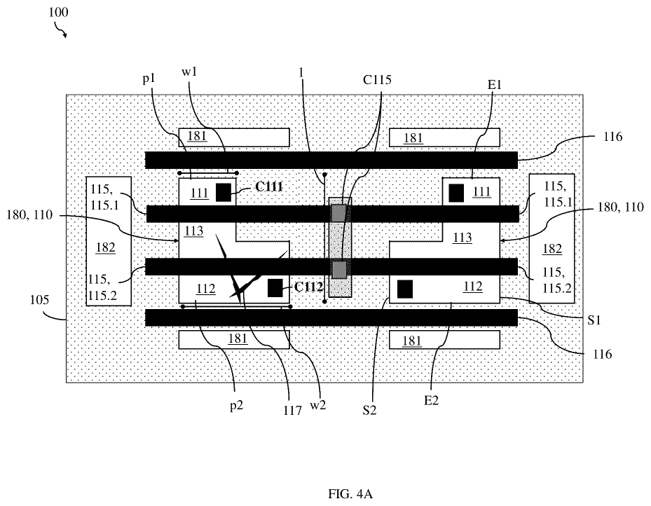

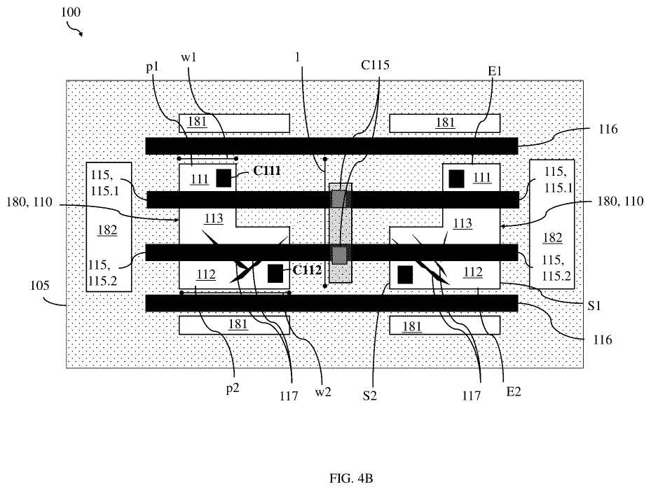

The design of the disclosed PUF cell 100 takes advantage of such dislocations to achieve random performance variations. Specifically, during PUF cell design a calibration process can be performed (as discussed in greater detail below with regards to the method embodiments). The calibration process includes predetermining certain dimensions associated with the active semiconductor region 180 to adjust inherent stress on the active semiconductor region and, thereby increase the likelihood, to some degree, that one or more dislocations will be present within the active semiconductor region following manufacturing. The goal of the calibration process is to ensure that the corresponding Idoff of any FET within a PUF cell manufactured according to the final design will have an Idoff within a relatively large Idoff range and further that the Idoff will be approximately equally as likely to be above or below some mid-level within that range (due to the probability of the occurrence of dislocations therein). Thus, for example, once a PUF cell 100 is manufactured according to PUF cell design with a pair of mirror-image FETs 110, the active semiconductor regions 180 of the two FETs 110 could: (a) have zero dislocations in both, as shown in FIG. 1, so both FETs have low Idoffs; (b) zero dislocations in one and one or more dislocations 117 in the other, as shown in FIG. 4A, so one FET has a low Idoff and the other has a higher Idoff; or (c) one or more dislocations 117 in both, as shown in FIG. 4B, so both FETs have higher Idoffs.

As mentioned above, FIG. 2 is a schematic diagram illustrating embodiments of a PUF 200 including a device (also referred to herein as a device under test (DUT) 201), which includes multiple PUF cells 100, as described in detail above. Within DUT 201, PUF cells 100 can be arranged in columns and rows. For example, in some embodiments, DUT 201 could include twenty PUF cells 100 arranged in two columns (e.g., see columns C0-C1) and ten rows (e.g., see rows R0-R9). It should be noted that FIG. 2 is not intended to be limiting and that, alternatively, such a DUT 201 could include less than twenty PUF cells (e.g., eighteen PUF cells, sixteen PUF cells, or even fewer PUF cells) or more than twenty PUF cells (e.g., twenty-two PUF cells, twenty-four PUF cells or even more PUF cells). Optionally, as illustrated, in each row of PUF cells 100, the same gate 115 can be shared by all PUF cells 100 in that row. That is, a first gate section 115.1 can extend laterally across p1 of each FET 110 of each PUF cell 100 in the same row and a second gate section 115.2, which is electrically connected to first gate section 115.1, can similarly extend laterally across p2 of each FET 110 of each PUF cell 100 in the same row. Alternatively, each PUF cell 100 could include discrete gates 115 (not shown). Similarly, dummy gates 116 can also be shared across all PUF cells 100 in the same row. Alternatively, each PUF cell 100 could include discrete dummy gates 116. As mentioned above, each PUF cell 100 can include semiconductor fill material regions (e.g., 181-182) adjacent to at least one end and/or at least one side of each active semiconductor region 180 therein. Optionally, as illustrated, first semiconductor fill material regions 181 can be shared between adjacent PUF cells 100 in the same column (e.g., first semiconductor fill material regions 181 can be shared between adjacent PUF cells in R0 and R1 of C0, first semiconductor fill material regions 181 can be shared between adjacent PUF cells in R1 and R2 of C0, and so on). Similarly, second semiconductor fill material regions 182 can be shared between adjacent PUF cells 100 in the same row (e.g., a second semiconductor fill material region 182 can be shared between adjacent PUF cells 100 in C0 and C1 of R0, a second semiconductor fill material region 182 can be shared between adjacent PUF cells 100 in C) and C1 of R1, and so on). Alternatively, each PUF cell 100 could have discrete, unshared semiconductor fill material regions (not shown).

PUF 200 can further include a set 290 of input/output pads. Set 290 can include: a first pad (P115), which is electrically connected to all gates 115 of all FETs 110 of all PUF cells 100 in DUT 201 (e.g., via gate contacts C115, as shown in FIG. 1); a second pad (P111), which is electrically connected to all source regions 111 of all FETs 110 of all PUF cells 100 in DUT 201 (e.g., via source contacts C111, as shown in FIG. 1); a third pad (P112), which is electrically connected to all drain regions 112 of all FETs 110 of all PUF cells 100 in DUT 201 (e.g., via drain contacts C112, as shown in FIG. 1); and, optionally, a fourth pad (P101), which is electrically connected to body regions of all FETs 110 of all PUF cells 100 in DUT 201 (e.g., via body contacts).

PUF 200 can further include peripheral circuitry, which is electrically connected to the set 290 of pads (e.g., P115, P111, P112, P101) and which is configured to facilitate performance of a read operation directed to DUT 201 (e.g., to output a valid response in response to a challenge). The peripheral circuitry can include bias voltage circuitry, which is configured to apply appropriate bias voltages on pads P115, P111, P112, and optionally, pad P101 so that a sum of all Idoffs of all FETs 110 of all PUF cells 100 in DUT 201 can be sensed at pad P112. For example, if the FETs 110 of the PUF cells 100 in DUT 201 are all NFETs, then off-state biasing conditions would include biasing pad P112 (which is electrically connected to all drain regions 112) with a positive supply voltage level (VDD) (e.g., 1.2 volts (V)) and grounding pad P111 (which is electrically connected to all source regions 111), pad P115 (which is electrically connected to all gates 115), and, optionally, pad P101 (which may be electrically connected to all body regions). As a result, a corresponding Idoff (if any) from each FET 110 of each PUF cell 100 can flow through pad P112 and the total Idoff from all FETs can be sensed, as discussed below. Alternatively, if the FETs 110 of the PUF cells 100 in DUT 201 are all PFETs, then off-state biasing conditions would include biasing pad P112 (which is electrically connected to all drain regions 112), pad P115 (which is electrically connected to all gates 115) and, optionally, pad P101 (which may be electrically connected to all body regions) with a positive supply voltage level (VDD) (e.g., 1.2 volts (V)) and grounding pad P111 (which is electrically connected to all source regions 111). As a result, a corresponding Idoff (if any) from each FET 110 of each PUF cell 100 can flow through pad P112 and the total Idoff from all FETs 110 can be sensed, as discussed below. Bias voltage circuitry, which can be configured to bias different pads as described above, is well known in the art. Thus, the details thereof have been omitted from the specification in order to allow the reader to focus on the salient aspects of the disclosed embodiments. The peripheral circuitry can also include a sense circuit 250, which is electrically connected to pad P115 and which is configured to generate and output a corresponding digital output (e.g., a bitstring) associated with DUT 201, based on the total Idoff sensed on pad P115. For example, in some embodiments, sense circuit 250 can include an analog-to-digital converter (ADC) 252 and a buffer 251 (also referred to herein as a driver amplifier), which is connected in series between pad P115 and ADC 252. Buffer 251 can be connected to receive the total Idoff from DUT 201 through pad P115 and can be configured to provide a low source impedance and sufficient output current to drive the input to ADC 252. ADC 252 can further be configured to convert the received input current (corresponding to the total Idoff) into a corresponding digital output signal (Dout) (e.g., a corresponding bitstring).

As mentioned above, FIG. 3 is a schematic diagram illustrating embodiments of a PUF 300 including multiple DUTs 201, as described above and illustrated in FIG. 2. In this case, multiple DUTs 201 can be incorporated into PUF 300 to, for example, achieve a stronger PUF (i.e., a PUF with a larger number of challenge-response pairs).

For example, PUF 300 could include some number (n) of DUTs 201. Six DUTs 201 (e.g., see DUT0-DUT5) are shown in FIG. 3 for illustration purposes. However, it should be understood that FIG. 3 is not intended to be limiting. Alternatively, any number of two or more DUTs 201 could be incorporated into the multi-DUT PUF 300 of FIG. 3.

In any case, PUF 300 can include the same number (n) of sets 290 of input/output pads, one for each DUT 201. As with set 290 of pads in PUF 200 of FIG. 2, as described above, each set 290 of pads in PUF 300 of FIG. 3 can include: a first pad (P115), which is electrically connected to all gates 115 of all FETs 110 of all PUF cells 100 in the corresponding DUT 201; a second pad (P111), which is electrically connected to all source regions 111 of all FETs 110 of all PUF cells 100 in the corresponding DUT 201; a third pad (P112), which is electrically connected to all drain regions 112 of all FETs 110 of all PUF cells 100 in the corresponding DUT 201; and, optionally, a fourth pad (P101), which is electrically connected to body regions of all FETs 110 of all PUF cells 100 in the corresponding DUT 201. Thus, a PUF 300, which has six DUTs 201, will have at least twenty-four pads and, optionally, may have an additional twenty fifth pad (Px) that can be left floating.

PUF 300 can further include peripheral circuitry, which is electrically connected to the sets 290 of pads to facilitate performance of read operations directed to the DUTs 201. The peripheral circuitry can include bias voltage circuitry, which is configured to apply appropriate bias voltages on pads P115, P111, P112, and optionally, pad P101 in each set 290 so that the sum of all Idoffs of all FETs 110 of all PUF cells 100 in a given DUT 201 can be sensed at pad P112 for that given DUT 201. Pad biasing can be performed in essentially the same manner as described above with regard to pad biasing in PUF 200 of FIG. 2. The peripheral circuitry can include n sense circuits 250. Each sense circuit 250 can be electrically connected to a corresponding pad P115 in a corresponding set 290 of pads for a corresponding DUT (e.g., DUT0, DUT1, etc.). Each sense circuit 250 can further be configured to generate and output a corresponding digital output (e.g., Dout0, Dout1, etc.), based on a total Idoff sensed on the corresponding pad P115. For example, in some embodiments, each sense circuit 250 can include an ADC 252 and a buffer 251, which is connected in series between a corresponding pad P115 for a corresponding DUT and the ADC 252. Buffer 251 can be connected to receive the total Idoff from the particular DUT 201 through the corresponding pad P115 and can be configured to provide a low source impedance and sufficient output current to drive the input to ADC 252. The ADC 252 can further be configured to convert the received input current (corresponding to the total Idoff) into a corresponding digital output signal (e.g., Dout0, Dout1, etc.). With peripheral circuitry, as described above, read operations could be concurrently or selectively directed to each of the DUTs 201 in PUF 300 by concurrently or selectively biasing the sets of pads. Thus, different digital output signals (e.g., Dout0, Dout1, etc.) could be concurrently or selectively generated by the sense circuits. Alternatively, the peripheral circuitry could include fewer than n sense circuits 250 (e.g., one sense circuit). In this case, the peripheral circuitry could also include a switching circuit, such as a multiplexer (not shown), which is configured to selectively connect one pad P115 to the sense circuit to facilitate performance of one read operation at a time directed to one of the DUTs 201.

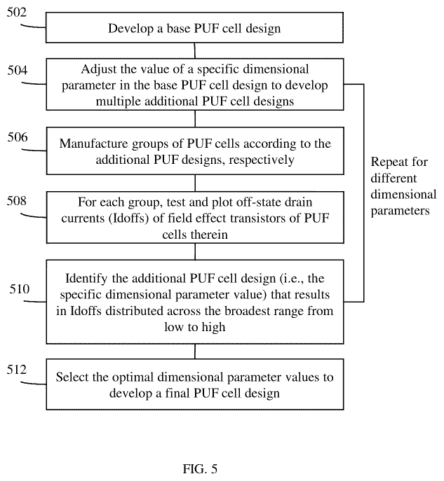

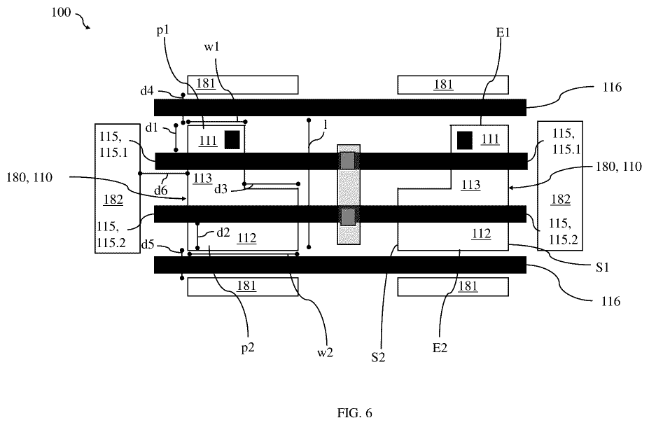

FIG. 5 is a flow diagram illustrating a design method, including a calibration process, for developing a final PUF cell design. The method can include developing a base PUF cell design (e.g., having a pair of mirror-image FETs 110, each with an essentially L-shaped active semiconductor region 180, as described in detail above and illustrated in FIG. 1) in a technology node at issue (see process 502). The method can further include adjusting the value of a specific dimensional parameter in the base PUF cell design to develop multiple additional PUF cell designs (see process 504). That is, the additional PUF cell designs developed at process 504 can be essentially the same except that the value of a specific dimensional parameter can be different within the different additional PUF cell designs. FIG. 6 shows a design layout for the PUF cell 100 of FIG. 1 annotated to show at least some of the different dimensions, which are associated with each active semiconductor regions 180 in the base PUF cell design and which could be adjusted at process 504. The different dimensions can include, but are not limited to: the length (l) of the active semiconductor region 180 between opposing ends (E1 and E2); the first width (w1) of the narrower first portion (p1); the second width (w2) of the wider second portion (p2); a first distance (d1) corresponding to the length of source region 111 between first gate section 115.1 and E1; a second distance (d2) corresponding to the length of drain region 112 between second gate section 115.2 and E2; a third distance (d3) (also referred to herein as a jog or step distance) along S2 between the narrower first portion and the wider second portion; a fourth distance (d4) between E1 and an adjacent first semiconductor fill material region 181 (if present); a fifth distance (d5) between E2 and an another adjacent first semiconductor fill material region 182 (if present); a sixth distance (d6) between S1 and a second semiconductor fill material region 182 (if present); a minimum distance between the active semiconductor region 180 of one FET and the active semiconductor region 180 of another FET 110 (if present) in the same PUF cell; a length of each first semiconductor fill material region 181 (if present) relative to the first and second portions of the active semiconductor region 180; a length of a second semiconductor fill material region 182 (if present) relative to the active semiconductor region 180, etc.

The method can include manufacturing groups of PUF cells according to the additional PUF cell designs, respectively (see process 506). For example, at process 506, a first group of PUF cells with a design specifying a first value for a specific dimensional parameter could be manufactured across an entire wafer (or portion of a wafer), second group of PUF cells with a design specifying a second value for a specific dimensional parameter could be manufactured across an entire wafer (or portion of a wafer), and so on. Subsequently, for each group, the off-state drain currents (Idoffs) for each of the field effect transistors in each of the PUF cells can be tested and plotted (see process 508). Furthermore, the additional PUF cell design (i.e., the specific dimensional parameter value) that results in Idoffs being distributed across the broadest range from low to high can be identified (see process 510).

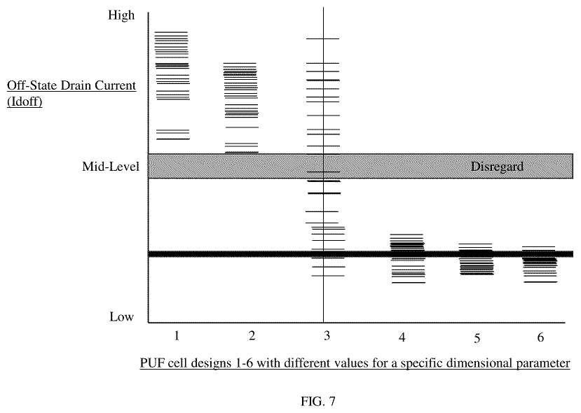

For example, FIG. 7 is a graph illustrating Idoffs plotted for six different PUF cell designs associated with different values for the same specific dimensional parameter (e.g., d4 between E1 and the adjacent first semiconductor fill material region 181) and further associated with the same values for all other dimensional parameters. As illustrated, Idoffs acquired from groups of PUF cells manufactured according to PUF cell designs 1 and 2 are all relatively high, indicating a relatively high likelihood of dislocations in any active semiconductor region. Idoffs acquired from groups of PUF cells manufactured according to PUF cell designs 4-6 are all relatively low, indicating a relatively low likelihood of dislocations in any active semiconductor region. However, Idoffs acquired from the group of PUF cells manufactured according to PUF cell design 3 are distributed across a wide range from low to high and are approximately equally as likely to be above or below the mid-level within that range, indicating the possibility of a broad range of numbers of dislocations (e.g., from zero to a relatively high number) is possible in any active semiconductor region.

Processes 504-510 can be repeated for at least some of the different dimensional parameters mentioned above and, optionally, for combinations thereof. Then, the optimal dimensional parameters for the PUF cell can be selected to develop the final PUF cell design (see process 512).

Once the final PUF cell design, an on-chip PUF (e.g., a PUF 200 as described in detail above and illustrated in FIG. 2 or a PUF 300 as described in detail above and illustrated in FIG. 3) could be manufactured. As mentioned above, such a PUF 200, 300 could be employed for cryptography (e.g., encryption and decryption), advanced authentication, etc.

Optionally, the PUF 200, 300 could also be monitored for early detection of structure degradation. Specifically, following fabrication, PUF 200, 300 could be subjected to a baseline physical failure analysis (PFA) using conventional PFA techniques (e.g., optical microscopes, laser-scanning microscopes, scanning electron microscopes, focused ion beam (FIB) microscopes, etc.) to map out all dislocations. PFA can be repeated (e.g., periodically, on demand, etc.) to detect any changes in dislocations (e.g., lengthening of previously mapped dislocations, additional dislocations, etc.), thereby providing both a security feature and a diagnostic tool for detecting early signs of PUF degradation.

It should be understood that techniques for forming the above-described PUF cells and PUFs (including, but not limited to, techniques for forming FETs, trench isolation regions, semiconductor fill material regions, interconnects, pads, middle of the line (MOL) features, back end of the line (BEOL) features, etc. therein) are well known in the art and technology node-dependent. Thus, the details thereof have been omitted from this specification in order to allow the reader to focus on the salient aspects of the disclosed embodiments (e.g., related to the structures of the PUF cells and PUFs themselves, the calibration process for determining the optimal dimensional parameters of the PUF cells, etc.).

In addition, it should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a field effect transistor including:
an active semiconductor region including:
a first portion having a first width; and
a second portion continuous with the first portion and having a second width that is greater than the first width; and
a gate including:
a first gate section traversing the first portion; and
a second gate section electrically connected to the first gate section and traversing the second portion.

2. The structure of claim 1, wherein the active semiconductor region includes a source region in the first portion adjacent to a first end, a drain region in the second portion adjacent to second end, and a shared source/drain region between the first gate section and the second gate section.

3. The structure of claim 1, further comprising:
at least one semiconductor fill material region adjacent to the active semiconductor region; and
an isolation region laterally surrounding the active semiconductor region and further laterally surrounding the at least one semiconductor fill material region.

4. The structure of claim 1,
wherein the active semiconductor region includes a first end, a second end opposite the first end, a first side, and a second side opposite the first side,
wherein the first end, the second end, and the first side are approximately linear with the first side being perpendicular to the first end and the second end,
wherein the second side is any of stepped and curved, and
wherein the structure further comprises:
semiconductor fill material regions parallel and adjacent to the first end, the second end, and the first side; and
an isolation region laterally surrounding the active semiconductor region and further laterally surrounding the semiconductor fill material regions.

5. The structure of claim 4, further comprising non-functional gates on the isolation region adjacent to the first end and adjacent to the second end, respectively.

6. The structure of claim 4,
wherein a semiconductor fill material region adjacent to the first side has a same length as the active semiconductor region, and
wherein two semiconductor fill material regions adjacent to the first end and the second end, respectively, have the second width.

7. The structure of claim 1, further comprising an additional field effect transistor, wherein the field effect transistor and the additional field effect transistor are symmetrical and the gate is shared between the additional field effect transistor and the field effect transistor.

8. A structure comprising:
a device including multiple cell structures, wherein each cell structure includes a field effect transistor including:
an active semiconductor region including:
a first portion having a first width; and
a second portion continuous with the first portion and having a second width that is greater than the first width; and
a gate including:
a first gate section traversing the first portion; and
a second gate section electrically connected to the first gate section and traversing the second portion,
wherein the active semiconductor region has a first end and a second end opposite the first end,
wherein the active semiconductor region includes a source region in the first portion adjacent to the first end, a drain region in the second portion adjacent to the second end, and a shared source/drain region between the first gate section and the second gate section; and
a set of pads for the device, wherein the pads in the set include: a first pad connected to gates of field effect transistors of the cell structures; a second pad connected to source regions of the field effect transistor of the cell structures; and a third pad connected to drain regions of the field effect transistors of the cell structures.

9. The structure of claim 8, further comprising a sense circuit connected to the third pad and configured to sum off-state drain currents of the field effect transistors and, based on a total off-state drain current, generate and output a corresponding digital output.

10. The structure of claim 8,
wherein each cell structure further includes:
at least one semiconductor fill material region adjacent to the active semiconductor region; and
an isolation region laterally surrounding the active semiconductor region and further laterally surrounding the at least one semiconductor fill material region, and
wherein at least some semiconductor fill material regions are shared between adjacent cell structures.

11. The structure of claim 8,
wherein, within each cell structure, the active semiconductor region includes a first end, a second end opposite the first end, a first side, and a second side opposite the first side,
wherein the first end, the second end, and the first side are approximately linear with the first side being perpendicular to the first end and the second end,
wherein the second side is any of stepped and curved,
wherein the cell structure further comprises:
semiconductor fill material regions parallel and adjacent to the first end, the second end, and the first side; and
an isolation region laterally surrounding the active semiconductor region and further laterally surrounding the semiconductor fill material regions, and
wherein at least some of the semiconductor fill material regions are shared between adjacent cell structures.

12. The structure of claim 11, wherein each cell structure further includes non-functional gates on the isolation region adjacent to the first end and adjacent to the second end, respectively.

13. The structure of claim 11,
wherein a semiconductor fill material region adjacent to the first side has a same length as the active semiconductor region, and
wherein two semiconductor fill material regions adjacent to the first end and the second end, respectively, have the second width.

14. The structure of claim 8,
wherein each cell structure further includes an additional field effect transistor,
wherein the field effect transistor and the additional field effect transistor are essentially symmetrical, and
wherein the gate is shared between the additional field effect transistor and the field effect transistor.

15. The structure of claim 8, wherein all field effect transistors of the cell structures include N-type field effect transistors.

16. The structure of claim 8, wherein all field effect transistors of the cell structures include P-type field effect transistors.

17. A structure comprising:
multiple devices, wherein each device includes multiple cell structures and each cell structure includes a field effect transistor including:
an active semiconductor region including:
a first portion having a first width; and
a second portion continuous with the first portion and having a second width that is greater than the first width; and
a gate including:
a first gate section traversing the first portion; and
a second gate section electrically connected to the first gate section and traversing the second portion,
wherein the active semiconductor region has a first end and a second end opposite the first end,
wherein the active semiconductor region includes a source region in the first portion adjacent to the first end, a drain region in the second portion adjacent to the second end, and a shared source/drain region between the first gate section and the second gate section; and
sets of pads for the devices, respectively, wherein the pads in each set for each device include at least: a first pad connected to gates of field effect transistors of the cell structures of the device; a second pad connected to source regions of the field effect transistor of the cell structures of the device; and a third pad connected to drain regions of the field effect transistors of the cell structures of the device.

18. The structure of claim 17, further comprising a sense circuit connected to all third pads of all sets, wherein, for each device, the sense circuit is configured to sum off-state drain currents of the field effect transistors of the cell structures and, based on a total off-state drain current, generate and output a corresponding digital output.

19. The structure of claim 17, wherein each cell structure further includes:
at least one semiconductor fill material region adjacent to the active semiconductor region; and
an isolation region laterally surrounding the active semiconductor region and further laterally surrounding the at least one semiconductor fill material region,
wherein at least some semiconductor fill material regions are shared between adjacent cell structures.

20. The structure of claim 17,
wherein each cell structure further includes an additional field effect transistor,
wherein the field effect transistor and the additional field effect transistor are essentially symmetrical, and
wherein the gate is shared between the additional field effect transistor and the field effect transistor.
